(19) United States
(12) Patent Application Publication
(10) Pub. No.: US 2026/0111142 A1
(43) Pub. Date: Apr. 23, 2026

(54) MEMORY APPARATUS, MEMORY SYSTEM AND OPERATION METHOD THEREOF

(71) Applicant: Yangtze Memory Technologies Holding Co., Ltd., Wuhan (CN)

(72) Inventors: Chunyuan Hou, Wuhan (CN); Zongliang Huo, Wuhan (CN); Jiawei Chen, Wuhan (CN); Mei Wang, Wuhan (CN); Wenjie Mu, Wuhan (CN)

(21) Appl. No.: 19/305,291

(22) Filed: Aug. 20, 2025

(30) Foreign Application Priority Data
Oct. 17, 2024 (CN) 202411455491.9

(51) Int. Cl. G06F 3/06; G11C 11/408; H01L 23/00; H01L 25/04; H10B 80/00

(52) U.S. Cl. CPC G06F 3/0655; G06F 3/0604; G06F 3/0673; H10B 80/00; H10W 90/00; G11C 11/4087; H10W 72/07254; H10W 72/247; H10W 72/944; H10W 80/743; H10W 90/722; H10W 90/792

(57) ABSTRACT

According to one aspect of the present disclosure, a memory apparatus is provided. The memory apparatus may include a first memory die and a die group stacked in a first direction. The die group may include M second memory dies stacked in the first direction. Each of the second memory dies may be connected to a third memory die and configured to perform data exchange at a bandwidth of (N*X) bits with the third memory die through N data channels. The first memory die may be connected to the third memory die. The first memory die may be configured to perform data exchange at a bandwidth of (N*X) bits with the third memory die through N data channels. The first memory die may be configured to replace a first data channel of the die group when a storage portion corresponding to the first data channel fails.

### CROSS-REFERENCE TO RELATED APPLICATIONS

This application claims the benefit of priority to Chinese Application No. 202411455491.9, filed on Oct. 17, 2024, which is incorporated herein by reference in its entirety.

### TECHNICAL FIELD

This disclosure relates to the field of semiconductor technology, such as a memory apparatus, a memory system, and an operation method thereof.

### BACKGROUND

With the continuous development of science and technology today, semiconductor devices are widely used in various electronic devices and products. For example, Dynamic Random Access Memory (DRAM), as a volatile memory, is a commonly used semiconductor memory device in computers.

### SUMMARY

According to one aspect of the present disclosure, a memory apparatus is provided. The memory apparatus may include a first memory die and a die group stacked in a first direction. The die group may include M second memory dies stacked in the first direction. Each of the second memory dies may be connected to a third memory die and configured to perform data exchange at a bandwidth of (N*X) bits with the third memory die through N data channels. M, N and X may be positive integers. The first memory die may be connected to the third memory die. The first memory die may be configured to perform data exchange at a bandwidth of (N*X) bits with the third memory die through N data channels. The first memory die may be configured to replace a first data channel of the die group when a storage portion corresponding to the first data channel fails.

In some implementations, the memory apparatus may further include P die groups stacked in the first direction. In some implementations, the first memory die may be configured to replace a first data channel of any one of the P die groups when a storage portion corresponding to the first data channel fails, and P is a positive integer.

In some implementations, the first memory die may include a first hybrid bonding layer. In some implementations, each second memory die of the M second memory dies may include a second hybrid bonding layer and a third hybrid bonding layer. In some implementations, the first memory die and the second memory die may be connected through the first hybrid bonding layer and the second hybrid bonding layer. In some implementations, two of the second memory dies adjacent in the first direction may be connected to the third hybrid bonding layer through the second hybrid bonding layer.

In some implementations, the first memory die may include a first bump bonding layer. In some implementations, each second memory die of the M second memory dies may include a second bump bonding layer and a third bump bonding layer. In some implementations, the first memory die and the second memory die may be connected through the first bump bonding layer and the second bump bonding layer. In some implementations, two of the second memory dies adjacent in the first direction may be connected to the third bump bonding layer through the second bump bonding layer.

In some implementations, the first memory die may be on one of two opposite sides of the P die groups in the first direction.

In some implementations, M may be 4. In some implementations, P may be 2 or 3.

In some implementations, a structure of the storage portion corresponding to the data channel of the first memory die may be the same as a structure of the storage portion corresponding to the data channel of a second memory die of the M second memory dies.

In some implementations, each of the first memory die and the second memory dies may include Y memory bank groups. In some implementations, each of the memory bank groups may include a plurality of memory banks. In some implementations, each of the memory banks may include a plurality of memory blocks. In some implementations, one data channel of the first memory die may correspond to (Y/N) memory bank groups of the first memory die. In some implementations, one data channel of a second memory die of the M second memory dies may correspond to (Y/N) memory bank groups of the second memory die. In some implementations, Y may be a positive integer and greater than N.

According to another aspect of the present disclosure, a memory system is provided. The memory system may include a memory apparatus and a third memory die. The third memory die and the memory apparatus may be stacked in a first direction. The memory apparatus may include a first memory die and a die group stacked in the first direction. The die group may include M second memory dies stacked in the first direction. Each of the second memory dies may be connected to the third memory die and configured to perform data exchange at a bandwidth of (N*X) bits with the third memory die through N data channels. M, N and X may be positive integers. The first memory die may be connected with the third memory die and configured to perform data exchange at a bandwidth of (N*X) bits with the third memory die through N data channels. n data channels of the first memory die and (M*N-n) data channels of the die group may be configured to collectively perform data exchange with the third memory die in parallel. n may be an integer, and 0≤n≤N.

In some implementations, the die group may be between the first memory die and the third memory die.

In some implementations, the memory apparatus may include P die groups stacked in the first direction. In some implementations, the first memory die may be configured to replace a first data channel of any one of the P die groups when a storage portion corresponding to the first data channel fails. In some implementations, P may be a positive integer.

In some implementations, the first memory die may include a first hybrid bonding layer. In some implementations, each second memory die of the M second memory dies may include a second hybrid bonding layer and a third hybrid bonding layer. In some implementations, the first memory die and the second memory die may be connected through the first hybrid bonding layer and the second hybrid bonding layer. In some implementations, two of the second memory dies adjacent in the first direction may be connected to the third hybrid bonding layer through the second hybrid bonding layer.

In some implementations, the first memory die may include a first bump bonding layer. In some implementations, each second memory die of the M second memory dies may include a second bump bonding layer and a third bump bonding layer. In some implementations, the first memory die and the second memory die may be connected through the first bump bonding layer and the second bump bonding layer. In some implementations, two of the second memory dies adjacent in the first direction may be connected to the third bump bonding layer through the second bump bonding layer.

In some implementations, M may be 4. In some implementations, P may be 2 or 3.

In some implementations, a structure of a storage portion corresponding to the data channel of the first memory die may be the same as a structure of a storage portion corresponding to the data channel of a second memory die of the M second memory dies.

In some implementations, each of the first memory die and the second memory dies may include Y memory bank groups. In some implementations, each of the memory bank groups may include a plurality of memory banks. In some implementations, each of the memory banks may include a plurality of memory blocks. In some implementations, one data channel of the first memory die may correspond to (Y/N) memory bank groups of the first memory die. In some implementations, one data channel of a second memory die of the M second memory dies may correspond to (Y/N) memory bank groups of the second memory die. In some implementations, Y may be a positive integer and greater than N.

In some implementations, the memory apparatus may include a first interface including a plurality of first data transmission interfaces. In some implementations, each of the first data transmission interfaces may correspond to one data channel. In some implementations, the third memory die may include a replacement control signal generation circuitry. In some implementations, the third memory die may include a selection circuitry including a signal input end and a plurality of data input ends. In some implementations, the signal input end of the selection circuitry may be connected to an output end of the replacement control signal generation circuitry. In some implementations, each of the data input ends of the selection circuitry may be connected to one of the first data transmission interfaces.

In some implementations, the replacement control signal generation circuitry may be configured to generate a corresponding replacement control signal based on an address of the data channel corresponding to a failed storage portion in a second memory die of the M second memory dies and an address of the data channel of the second memory die currently requiring data exchange with the third memory die. In some implementations, the selection circuitry may be configured to replace the data channel corresponding to the failed storage portion in the second memory die with the data channel in the first memory die based on the corresponding replacement control signal.

In some implementations, the replacement control signal generation circuitry may include a storage component, a latch circuitry, and a decoding circuitry. In some implementations, the storage component may be connected to an input end of the latch circuitry. In some implementations, an output end of the latch circuitry may be connected to a first input end of the decoding circuitry. In some implementations, a second input end of the decoding circuitry may be connected to a signal line of the memory system. In some implementations, an output end of the decoding circuitry may be connected to the signal input end of the selection circuitry.

In some implementations, the storage component may be configured to store the address of a data channel corresponding to the failed storage portion in the second memory die. In some implementations the latch circuitry may be configured to latch the address of the data channel corresponding to the failed storage portion in the second memory die after the memory system is powered on. In some implementations, the decoding circuitry may be configured to generate a replacement control signal based on the address of the data channel corresponding to the failed storage portion in the second memory die and the address of the data channel of the second memory die currently requiring data exchange with the third memory die.

In some implementations, the third memory die may further include a second interface including a plurality of second data transmission interfaces. In some implementations, each of a plurality of output ends of the selection circuitry may be connected to one of the second data transmission interfaces. In some implementations, a number of the first data transmission interfaces may be greater than the number of the second data transmission interfaces.

According to a further aspect of the present disclosure, a method of operating a memory system is provided. The method may include collectively performing data exchange at a bandwidth of (M*N*X) bits in parallel between (M*N) data channels of M second memory dies of a die group stacked in a first direction and a third memory die. M, N, and X may be positive integers. When a storage portion corresponding to the n data channels of the die group fails, the method may include replacing n data channels corresponding to a failed storage portion of the die group with n data channels in a first memory die of the die group stacked in the first direction. n may be an integer and 1≤n≤N. The method may include collectively performing data exchange at a bandwidth of (M*N*X) bits in parallel between the n data channels of the first memory die, the (M*N−n) data channels of the die group and the third memory die.

In some implementations, when the storage portion corresponding to the n data channels of the die group fails, replacing the n data channels corresponding to the failed storage portion of the die group with the n data channels in the first memory die of the die group stacked in the first direction may include, when the storage portion corresponding to the n data channels of any one of P die groups of the memory system stacked in the first direction fails, replacing the n data channels corresponding to the failed storage portion of the die groups with the n data channels in the first memory die. In some implementations, P may be a positive integer.

In some implementations, the die group may be between the first memory die and the third memory die.

In some implementations, when the storage portion corresponding to the n data channels of the die group fails, replacing the n data channels corresponding to the failed storage portion of the die group with the n data channels in the first memory die of the die group stacked in the first direction may include generating, by a replacement control signal generation circuitry, a corresponding replacement control signal based on an address of the data channel corresponding to the failed storage portion in a second memory die and an address of the data channel of the second memory die currently requiring data exchange with the third memory die. In some implementations, when the storage portion corresponding to the n data channels of the die group fails, replacing the n data channels corresponding to the failed storage portion of the die group with the n data channels in the first memory die of the die group stacked in the first direction may include replacing, by a selection circuitry, the data channel corresponding to the failed storage portion in the second memory die with the data channel in the first memory die based on the corresponding replacement control signal.

In some implementations, generating, by the replacement control signal generation circuitry, the corresponding replacement control signal based on the address of the data channel corresponding to the failed storage portion in the second memory die and the address of the data channel of the second memory die currently requiring data exchange with the third memory die may include storing, by a storage component, the address of the data channel corresponding to the failed storage portion in the second memory die. In some implementations, generating, by the replacement control signal generation circuitry, the corresponding replacement control signal based on the address of the data channel corresponding to the failed storage portion in the second memory die and the address of the data channel of the second memory die currently requiring data exchange with the third memory die may include latching, by a latch circuitry, the address of the data channel corresponding to the failed storage portion in the second memory die after the memory system is powered on. In some implementations, generating, by the replacement control signal generation circuitry, the corresponding replacement control signal based on the address of the data channel corresponding to the failed storage portion in the second memory die and the address of the data channel of the second memory die currently requiring data exchange with the third memory die may include generating, by a decoding circuitry, a corresponding replacement control signal based on the address of the data channel corresponding to the failed storage portion in the second memory die and the address of the data channel of the second memory die currently requiring data exchange with the third memory die.

In some implementations, the method may include generating, by the decoding circuitry, a replacement control signal of a first value based on the address of the data channel of the second memory die currently requiring data exchange with the third memory die being the same as the address of first data channel corresponding to the failed storage portion in the second memory die. In some implementations, different first data channels may generate different first values. In some implementations, the method may include generating, by the decoding circuitry, a replacement control signal of a second value based on the address of the data channel of the second memory die currently requiring data exchange with the third memory die being different from the address of the first data channel corresponding to the failed storage portion in the second memory die.

In some implementations, the method may include replacing, by the selection circuitry, the first data channel corresponding to the first value with the data channel in the first memory die based on the value of the replace control signal being the first value.

In examples of the present disclosure, a first memory die is added, and when the storage portion corresponding to the first data channel of the die group fails, replacing the first data channel corresponding to the failed storage portion with the data channel in the first memory die. In the first aspect, when the storage portion corresponding to the first data channel of the die group fails, the die group may still perform data exchange at a bandwidth of (M*N*X) bits with the third memory die in parallel, so that the yield of the memory device can be effectively improved. In the second aspect, the solution provided by examples of the present disclosure is a data channel level replacement, which not only solves the problem of yield loss caused by failures in the memory cell array, but also addresses the problem of yield loss caused by failures in the peripheral circuitry.

### BRIEF DESCRIPTION OF THE DRAWINGS

FIG. 1 is a schematic diagram of the structure of an electronic device provided by examples of the present disclosure.

FIG. 2 is a schematic diagram of the composition structure of a memory device provided by examples of the present disclosure.

FIG. 3 is a schematic diagram of the structure of a memory device provided by examples of the present disclosure.

FIG. 4 is a first schematic diagram of the composition structure of a memory apparatus provided by examples of the present disclosure.

FIG. 5 is a first schematic diagram of the data channel of a memory apparatus provided by examples of the present disclosure.

FIG. 6 is a second schematic diagram of the composition structure of a memory apparatus provided by examples of the present disclosure.

FIG. 7 is a second schematic diagram of the data channel of a memory apparatus provided by examples of the present disclosure.

FIG. 8a is a third schematic diagram of the composition structure of a memory apparatus provided by examples of the present disclosure.

FIG. 8b is a fourth schematic diagram of the composition structure of a memory apparatus provided by examples of the present disclosure.

FIG. 9 is a fifth schematic diagram of the composition structure of a memory apparatus provided by examples of the present disclosure.

FIG. 10a is a first schematic diagram of the composition structure of a memory system provided by examples of the present disclosure.

FIG. 10b is a second schematic diagram of the composition structure of a memory system provided by examples of the present disclosure.

FIG. 11 is a third schematic diagram of the composition structure of a memory system provided by examples of the present disclosure.

FIG. 12 is a fourth schematic diagram of the composition structure of a memory system provided in examples of the present disclosure.

FIG. 13 is a first schematic diagram of the structure of a memory system provided by examples of the present disclosure.

FIG. 14 is a second schematic diagram of the structure of a memory system provided by examples of the present disclosure.

FIG. 15 is a schematic diagram of the structure of a selection circuitry provided by examples of the present disclosure.

FIG. 16 is a schematic diagram of the structure of a replacement control signal generation circuitry provided by examples of the present disclosure.

FIG. 17 is a flowchart of a method of operating a memory system provided by examples of the present disclosure.

### DETAILED DESCRIPTION

The example implementations disclosed in the present disclosure will be described in more detail below with reference to the accompanying drawings. Although example implementations of the present disclosure are shown in the accompanying drawings, it should be understood that the present disclosure may be implemented in various forms and should not be limited by the specific implementations set forth herein. Rather, the implementations are provided to enable a more thorough understanding of the present disclosure and to fully convey the scope of the present disclosure to those skilled in the art.

In the following description, a large number of specific details are provided to provide a more thorough understanding of the present disclosure. However, it will be apparent to those skilled in the art that the present disclosure can be implemented without one or more of the details. In other examples, in order to avoid confusion with the present disclosure, some well-known technical features in the art have not been described; That is, not all features of the actual implementation will be described herein, and well-known functions and structures will not be described in detail.

In the figures, the same reference numbers always indicate the same elements.

It should be understood that spatial relationship terms herein such as “below”, “under”, “lower”, “beneath”, “above”, “upper”, etc. can be used for ease of description to describe the relationship between one element or feature and another element or feature shown in the figures. It should be understood that in addition to the orientation shown in the figures, the spatial relationship terms are also intended to include the different orientations of devices in use and operation. For example, if the devices in the figures are flipped, then the element or feature described as “below” or “under” or “beneath” another element will be oriented “above” the other element or feature. Therefore, the example terms “under” and “below” may include both upper and lower orientations. The device can be oriented additionally (rotated 90 degrees or other orientations) and the spatial descriptive terms used herein are explained accordingly.

The terms used herein are only for the purpose of describing specific examples and are not used as limitation of the present disclosure. When used herein, “a”, “an”, and “the” in singular form are also intended to include the plural form, unless the context clearly indicates otherwise. It should also be understood that the terms ‘composition’ and/or ‘including’, when used in the specification, determine the presence of the described features, integers, steps, operations, elements, and/or components, but do not exclude the presence or addition of one or more other features, integers, steps, operations, elements, components, and/or groups. When used herein, the term “and/or” includes any and all combinations of the listed related items.

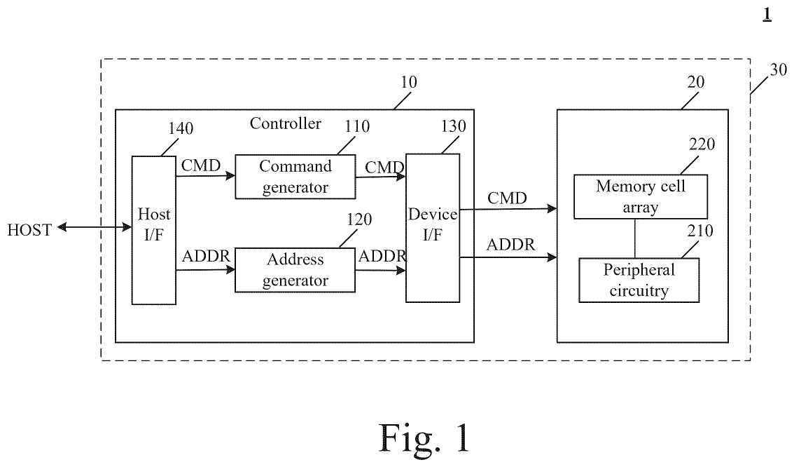

FIG. 1 is a schematic diagram of an electronic device 1 according to an example of the present disclosure. Electronic device 1 may be mobile phone, desktop computer, laptop computer, tablet computer, vehicle computer, game console, printer, positioning device, wearable electronic device, smart sensor, virtual reality (VR) device, augmented reality (AR) device, or any other suitable electronic device with memory therein.

As shown in FIG. 1, electronic device 1 may include a host and an electronic system 30. The electronic system 30 has one or more memory systems 20 and a controller 10. The host can be a processor of an electronic device such as Central Processing Unit (CPU), or System on Chip (SoC) such as Application Processor (AP). The host can be configured to send or receive data to/from the memory system 20. The controller 10 is coupled to the memory system 20 and the host, and configured to control the memory system 20. The controller 10 can manage data stored in the memory system 20 and communicate with the host.

The controller 10 can be configured to control the operations of the memory system 20, such as read, erase, write, and refresh operations. In some implementations, the controller 10 is also configured to process error correction codes (ECCs) for data read from or written to the memory system 20. The controller 10 can also perform any other suitable functions, such as formatting the memory system 20.

In some examples, the controller 10 and one or more memory systems 20 may be integrated into various types of memory devices. For example, the controller 10 may be integrated into the northbridge of computer motherboard or directly integrated into computer CPU, and multiple memory systems 20 may be integrated into memory bars. That is, the electronic system 30 may be implemented and packaged into different types of terminal electronic products.

The controller 10 can send or receive data to/from the host, and may send a command CMD and an address ADDR to the memory system 20. The controller 10 may include a command generator 110, an address generator 120, a device interface 130, and a host interface 140. The host interface 140 may receive a command CMD and an address ADDR from the host, command generator 110 may generate access commands, refresh commands, etc. by decoding the command CMD received from the host, and may provide the access commands and refresh commands to the memory system 20 through the device interface 130. The access commands may be a signal indicating the memory system 20 to write or read data by accessing rows of the memory cell array 220 corresponding to the address ADDR. The refresh commands may be a signal indicating the memory system 20 to read and rewrite data by accessing the rows of the memory cell array 220 corresponding to the refreshed address ADDR.

The address generator 120 in the controller 10 may generate row and column addresses to be accessed in the memory cell array 220 by decoding the address ADDR received from the host interface 140. Additionally, the memory system 20 may generate addresses of memory banks to be accessed when memory cell array 220 includes multiple memory banks.

The controller 10 may control memory operations such as writing and reading by providing various signals to the memory system 20 via the device interface 130. For example, the controller 10 may provide write commands to the memory system 20. The write commands are to indicate the memory system 20 to perform a write operation to store data in the memory system 20.

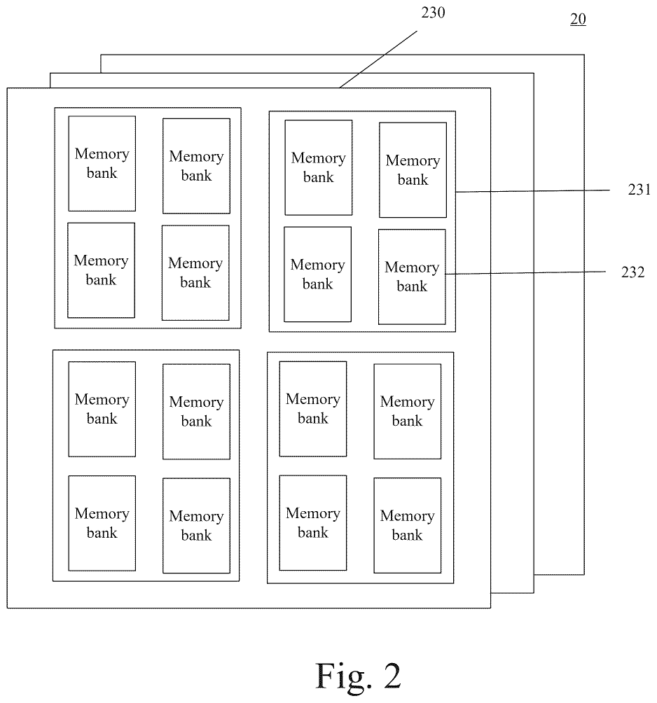

In some examples, as shown in FIG. 2, the memory system 20 includes at least one chip 230, each chip 230 includes at least one memory bank group 231, each memory bank group 231 includes at least one memory bank 232, and each memory bank 232 includes at least one memory block 501. It should be noted that the number of chips 230 in the memory system 20 and the number of memory banks 232 in the memory bank group 231 in FIG. 2 are only examples, and the present disclosure is not limited to thereto.

In some examples, each memory block includes a portion of memory cell array 220 and a portion of peripheral circuitry 210. The memory cell array includes multiple memory cell rows and multiple memory cell columns, with each memory cell row coupled to a corresponding word line and each memory cell column coupled to a corresponding bit line. Peripheral circuitry 210 may write or read data to/from memory cell array 220 based on the command CMD and address ADDR received from the controller 10, or provide control signals CTRL for refreshing the memory cells included in the memory cell array 220 to the row decoder and column decoder. In other words, the peripheral circuitry 210 may perform all the operations to process data in the memory cell array 220. The peripheral circuitry 210 may include control circuitry for each memory block such as Sensing Amplifier (SA) and Word Line Driver (WLD), control circuitry for each memory bank such as row decoder and column decoder, and control circuitry for all the memory banks such as command buffer, command decoder, address buffer, data input/output buffer, mode register, etc.

The memory system 20 may include Random Access Memory (RAM), such as Dynamic Random Access Memory (DRAM), Synchronous DRAM (SDRAM), Static RAM (SRAM), Double Data Rate SDRAM (DDR SDRAM), DDR2 SDRAM, DDR3 SDRAM, Phase Change RAM (PRAM), Magnetic RAM (MRAM), Resistive RAM (RRAM), etc. DRAM is used as an example memory device for illustration below.

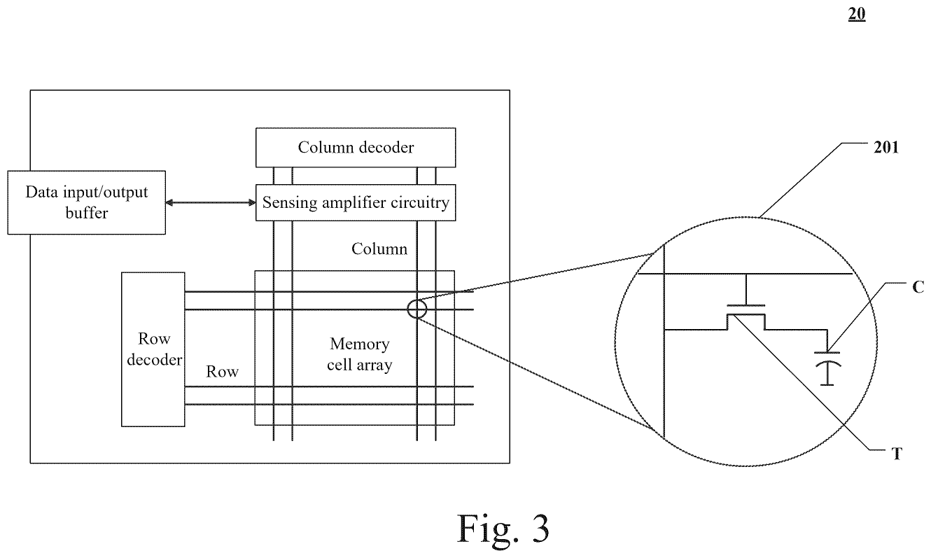

FIG. 3 is a schematic diagram of a dynamic random access memory according to an example of the present disclosure. Referring to FIG. 3, the dynamic random access memory includes a memory cell array and a peripheral circuitry. The memory cell array includes multiple memory cells 201 arranged in an array, each memory cell 201 including a transistor T and a capacitor C. The word line is coupled to the gate of the transistor T, and the bit line is coupled to the drain of the transistor T. The main principle of a memory cell is to use the amount of charge stored in a capacitor to represent whether a binary bit is 1 or 0. The memory cells are arranged in an array, and the memory cell array specifies addresses using rows and columns. By specifying the intersection points of rows and columns (by specifying the row and column addresses of DRAM), the controller can independently access various memory cells in the DRAM chip and perform read, write, or refresh operations on the data stored therein.

It should be noted that in an example of the present disclosure, a memory cell including a capacitor and a transistor (1T1C) is taken as an example for illustration. The present disclosure is not limited thereto. The memory cell in the present disclosure can also be of an nT0C architecture without capacitors and an architecture such as 1TnC, 2TnC, etc., without limitation.

With the development of dynamic random access memory technology, the size of memory cells is becoming smaller and smaller. The array architecture of the memory cells has evolved from 8F² to 6F² and then to 4F², and the architecture of transistors in the memory cells has gradually developed from planar array transistor to vertical gate transistor, thus forming the architecture of three-dimensional memory.

With the increasing demand for integration of memory device, stacking the memory device in three dimensions in a vertical direction can achieve large capacity and bandwidth. In some examples, a stacking method of 3D memory device is to stack and package selected memory dies after testing, e.g., namely, chip to chip (D2D) stacking. The method may avoid a failure of single-layer chips leading to a failure of the entire 3D memory. However, D2D stacking packaging process is complex and difficult, and a new failure mode is easily introduced during the packaging process. In some examples, wafer-to-wafer (W2W) stacking packaging can be applied, which can greatly simplify the stacking packaging process. However, due to the lack of chip selection in the wafer, the overall yield of 3D memory device is easily reduced due to the failure of single-layer chips.

The following implementations are proposed in the present disclosure.

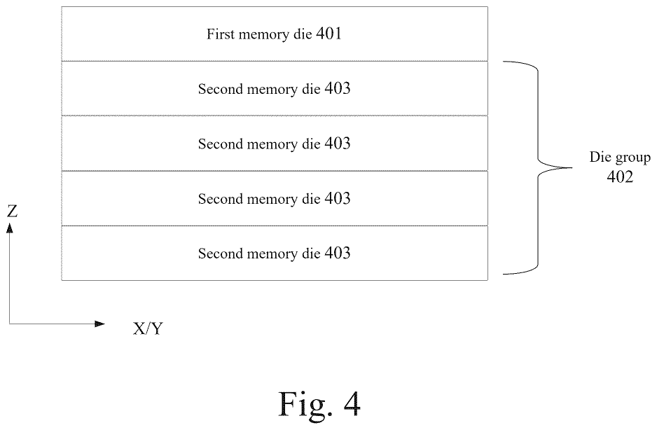

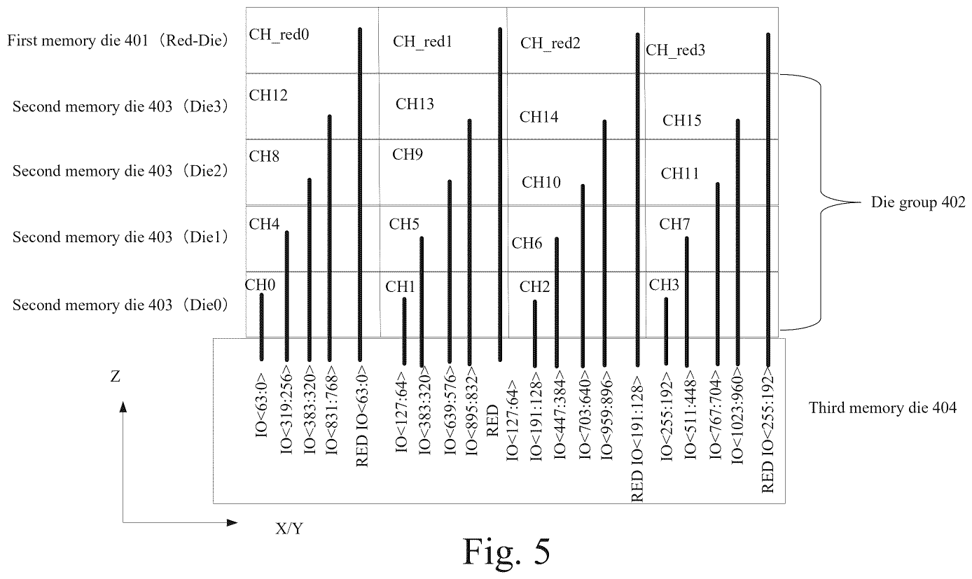

A memory apparatus is provided in an example in the present disclosure, as shown in FIGS. 4 and 5. The memory apparatus may include a first memory die 401 and a die group 402 stacked in a first direction, where the die group 402 includes M second memory dies 403 stacked in the first direction, each of the second memory dies 403 is connected to a third memory die 404 and configured to perform data exchange at a bandwidth of (N*X) bits with the third memory die 404 through N data channels, where M, N and X are positive integers. The first memory die 401 is connected to the third memory die 404, and configured to perform data exchange at a bandwidth of (N*X) bits with the third memory die 404 through N data channels, and to replace a first data channel of the die group 402 when a storage portion corresponding to the first data channel fails.

The first direction here may be understood as Z-axis direction in the figures of the present disclosure.

In an example of the present disclosure, the die group 402 may also be referred to as memory rank. Each of the M second memory dies 403 in the die group 402 has N data channels, and the M second memory dies 403 in the die group 402 have a total of (M*N) data channels, each of which may perform data exchange at a bandwidth of X bits with the third memory die 404, so that the (M*N) data channels may perform data exchange at a bandwidth of (M*N*X) bits with the third memory die 404 in parallel. The first memory die 401 has the same number of data channels as the second memory die 403, and each data channel of the first memory die 401 may transmit data with the same number of bits as each data channel of the second memory die 403.

In an example of the present disclosure, the first data channel of the die group 402 may be understood as any one of (M*N) data channels of the die group 402.

In an example of the present disclosure, a first memory die 401 is added. When a storage portion corresponding to a first data channel of the die group 402 fails, the first data channel corresponding to the failed storage portion may be replaced with a data channel in the first memory die 401. In the first aspect, when a storage portion corresponding to a first data channel of the die group 402 fails, the die group 402 may still perform data exchange at a bandwidth of (M*N*X) bits with the third memory die 404 in parallel, thereby effectively improving the yield of the memory device. In the second aspect, the solution provided by examples of the present disclosure is a data channel level replacement, which not only solves the problem of yield loss caused by failures in the memory cell array, but also addresses the problem of yield loss caused by failures in peripheral circuitry.

In some examples, as shown in FIG. 4, the first memory die 401 is on one of two opposite sides of the die group 402 in the first direction (Z-axis direction). The present disclosure is not limited thereto. In an example of the present disclosure, the first memory die 401 may also be between two of the second memory dies 403 of the die group 402 adjacent in the first direction (Z-axis direction).

In a non-limiting example of the present disclosure, as shown in FIG. 5, the die group 402 may include four second memory dies 403 (Die0-Die3), each of the second memory dies 403 has four data channels, and Die0-Die3 include a total of 16 data channels (CH0-CH15), each of which may transmit 64 bits of data. That is, the die group 402 may perform data exchange at a bandwidth of 1024 bits with the third memory die 404 in parallel, but examples of the present disclosure are not limited thereto. In a non-limiting example of the present disclosure, as shown in FIG. 5, the third memory die (Red˜Die) includes four data channels (CH-red0˜CH-red3), but examples of the present disclosure are not limited thereto.

In an example of the present disclosure, a second memory die 403 is connected to the third memory die 404, and the first memory die 401 is connected to the third memory die 404. Each of the second memory die 403 and the first memory die 401 may be connected to the third memory die 404 through a connection structure extending in the first direction. The material of the connection structure here includes conductive materials, which may be one of doped semiconductor materials (such as doped silicon, doped germanium, etc.), conductive metal nitrides (such as titanium nitride, tantalum nitride, etc.), metal materials (such as aluminum, copper, tungsten, titanium, tantalum, etc.), and metal semiconductor compounds (such as tungsten silicide, cobalt silicide, titanium silicide, etc.).

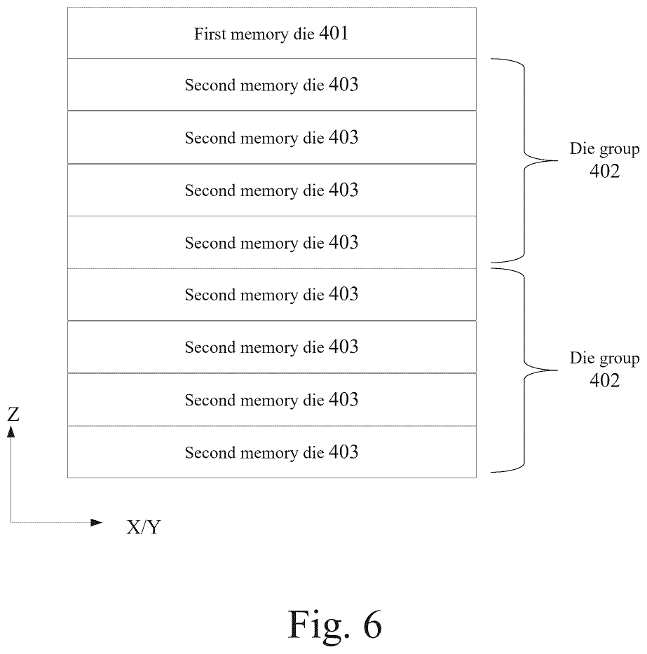

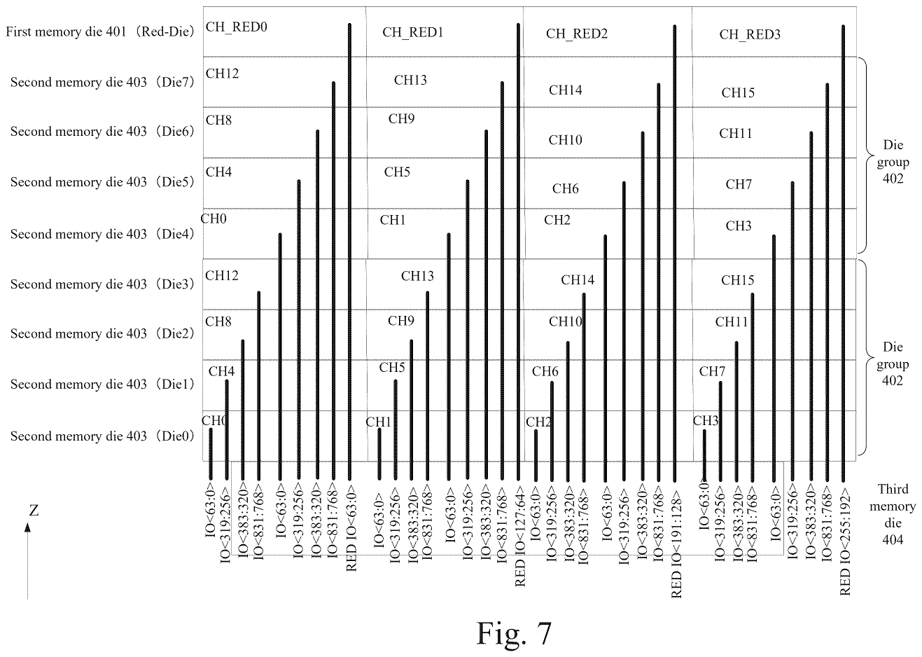

In some examples, as shown in FIGS. 6 and 7, the memory apparatus includes P die groups 402, and the P die groups 402 are stacked in the first direction (Z-axis direction). The first memory die 401 is configured to replace a first data channel of any one of the P die groups 402 when a storage portion corresponding to the first data channel fails, where P is a positive integer.

As shown in FIGS. 6 and 7, the memory apparatus may include multiple die groups 402, which may perform data exchange with the third memory die 404 in parallel. M second memory dies 403 in each die group 402 may perform data exchange with the third memory die 404 in parallel. When a storage portion corresponding to a first data channel of any one of the multiple die groups 402 fails, the first data channel may be replaced with a data channel in the first memory die 401, so that the die group 402 can perform data exchange at a bandwidth of (M*N*X) bits with the third memory die 404 in parallel.

In some examples, M is 4 and P is 2 or 3.

It should be noted that the values of M and P listed in examples described above are only examples and are not intended to limit the values of M and P. The values of M and P may also be set according to actual needs.

In an example of the present disclosure, as shown in FIG. 7, a memory system may include two die groups, one die group 402 includes 4 second memory dies 403 (Die0˜Die3), another die group includes 4 second memory dies (Die4˜Die7), each of the second memory dies 403 has 4 data channels, Die0˜Die3 includes a total of 16 data channels (CH0˜CH15), Die0˜Die3 includes a total of 16 data channels (CH0˜CH15), and Die4˜Die7 includes a total of 16 data channels (CH0˜CH15), each of which may transmit 64 bits of data. That is, the die group 402 may perform data exchange at a bandwidth of 1024 bits with the third memory die 404 in parallel, but examples of the present disclosure are not limited thereto. In an example of the present disclosure, as shown in FIG. 5, the third memory die (Red˜Die) may include four data channels (CH-red0˜CH-red3), but examples of the present disclosure are not limited thereto.

In an example of the present disclosure, the memory apparatus may include a first memory die 401, but not limited to this. In some examples, the quantity of the first memory die 401 may be adjusted accordingly from the perspectives of yield and cost, so that the memory device may achieve a high level of yield and cost savings.

In an example of the present disclosure, the die group 402 and the first memory die 401 are stacked in the first direction, and multiple second memory dies 403 of the die group 402 are stacked in the first direction, which may save the area of the memory apparatus and promote miniaturization of the memory apparatus. The first memory die 401 and the second memory die 403 may be stacked in the first direction by bonding.

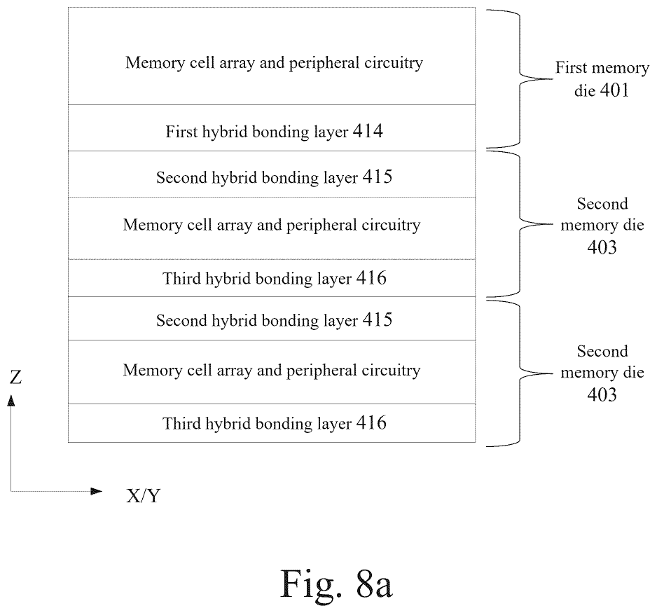

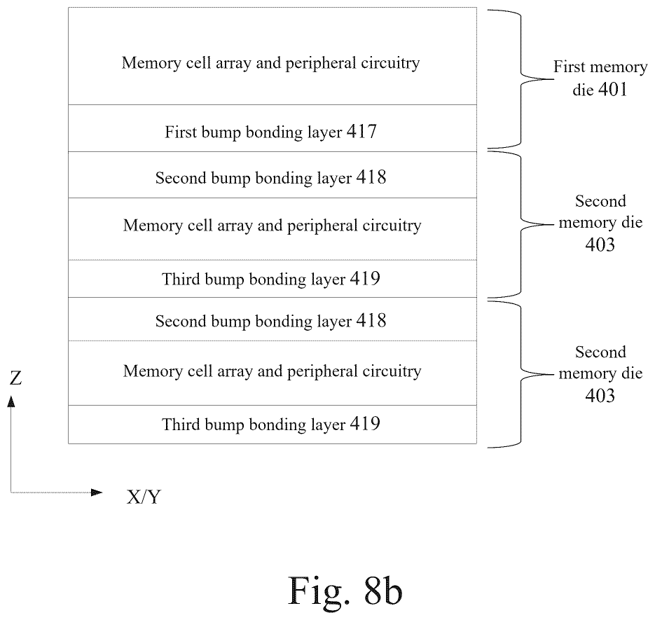

In some examples, as shown in FIG. 8a, the first memory die 401 includes a first hybrid bonding layer 414, and the second memory die 403 includes a second hybrid bonding layer 415 and a third hybrid bonding layer 416. The first memory die 401 and the second memory die 403 are connected through the first hybrid bonding layer 414 and the second hybrid bonding layer 415. Two of the second memory dies 403 adjacent in the first direction are connected to the third hybrid bonding layer 416 through the second hybrid bonding layer 415.

As described in the above examples, the first memory die 401 and the second memory die 403 may be stacked in the first direction through hybrid bonding. The corresponding hybrid bonding layers described above may include a dielectric layer in which corresponding bonding structures are set. The bonding structures in the connected hybrid bonding layers are connected. Materials of the bonding structures here include conductive materials such as tungsten, cobalt, copper, aluminum, nickel, silicide, or any combination thereof.

In an example of the present disclosure, the first memory die 401 and the second memory die 403 may be formed on the same or different wafers and then bonded together through hybrid bonding. By using hybrid bonding, the first memory die 401 and the second memory die 403 may be stacked in the first direction, so that the area of the memory apparatus may be further saved, which facilitates memory-device miniaturization.

In some examples, as shown in FIG. 8b, the first memory die 401 includes a first bump bonding layer 417, and the second memory die 403 includes a second bump bonding layer 418 and a third bump bonding layer 419. The first memory die 401 and the second memory die 403 are connected through the first bump bonding layer 417 and the second bump bonding layer 418, and two of the second memory dies 403 adjacent in the first direction are connected to the third bump bonding layer 419 through the second bump bonding layer 418.

As described in the above examples, the first memory die 401 and the second memory die 403 may also be stacked in the first direction through bump bonding. The corresponding bump bonding layers described above include bump structures, and the bump structures in the connected bump bonding layers are connected. Materials of the bump structures here include conductive materials such as tungsten, cobalt, copper, aluminum, nickel, silicide, or any combination thereof.

In an example of the present disclosure, the first memory die 401 and the second memory die 403 may be formed on the same or different wafers and then bonded together by bump bonding. By using bump bonding, the first memory die 401 and the second memory die 403 may be stacked in the first direction, so that the area of the memory device may be further saved, which facilitates the development of miniaturization of the memory device.

In an example of the present disclosure, each of the first memory die 401 and the second memory die 403 may include a first semiconductor structure and a second semiconductor structure stacked in the first direction. The first semiconductor structure includes a memory cell array, and the second semiconductor structure includes a first portion of peripheral circuitry, including but not limited to sensing amplifier circuitry, word line drive circuitry, row decoders, and column decoders. Here, the first and second semiconductor structure of the first memory die 401 or the second memory die 403 may be formed on the same wafer or on different wafers, and then bonded together through hybrid bonding. The first and second semiconductor structure of the first memory die 401 or the second memory die 403 are stacked in the first direction, so that the area of the memory device may be further saved.

In some examples, as shown in FIG. 6, the first memory die 401 is on one of two opposite sides of the P die groups 402 in the first direction (Z-axis direction).

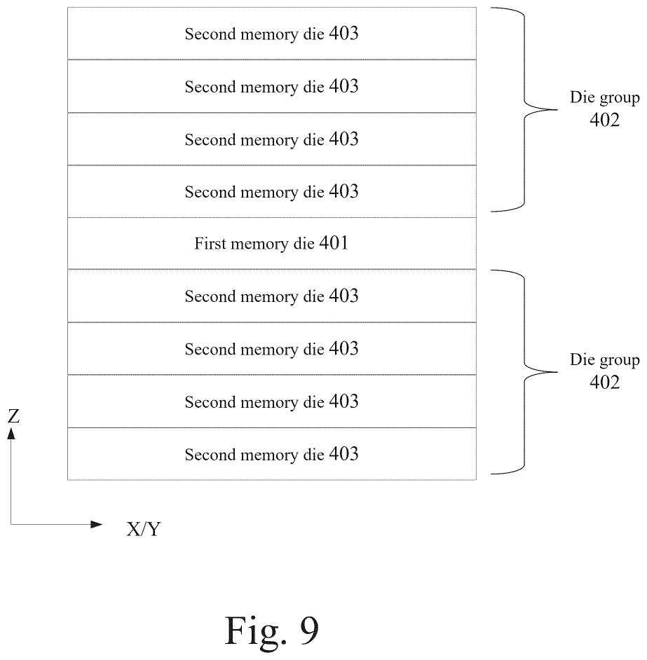

In an example of the present disclosure, as shown in FIG. 9, the first memory die 401 may also be between two die groups 402 adjacent in the first direction (Z-axis direction).

In some other examples, the first memory die 401 may also be between two of the second memory dies 403 of the die group 402 adjacent in the first direction.

In some examples, the structure of the storage portion corresponding to the data channel of the first memory die 401 is the same as the structure of the storage portion corresponding to the data channel of the second memory die 403.

In an example of the present disclosure, the first memory die 401 and the second memory die 403 have the same structure except for the connection structure with the third memory die 404. Other structures here include the structure of the storage portion, which includes a memory cell array and peripheral circuitry.

Here, the structure of the storage portion corresponding to the data channel of the first memory die 401 is the same as the structure of the storage portion corresponding to the data channel of the second memory die 403. It can be understood that the structure of the memory cell array of the first memory die is the same as the structure of the memory cell array of the second memory die, and the structure of the peripheral circuitry of the first memory die is the same as the structure of the peripheral circuitry of the second memory die.

In some examples, each of the first memory die 401 and the second memory dies 403 includes Y memory bank groups. The memory bank groups include a plurality of memory banks, and each of the memory banks includes a plurality of memory blocks. One data channel of the first memory die 401 corresponds to (Y/N) memory bank groups of the first memory die 401, and one data channel of the second memory die 403 corresponds to (Y/N) memory bank groups of the second memory die 403. Y is a positive integer and greater than N.

In some examples, each of the first memory die 401 and the second memory die 403 includes 16 memory bank groups, and has 4 data channels. One data channel of the first memory die 401 corresponds to 4 memory bank groups of the first memory die 401, and one data channel of the second memory die 403 corresponds to 4 memory bank groups of the second memory die 403. The present disclosure is not limited thereto.

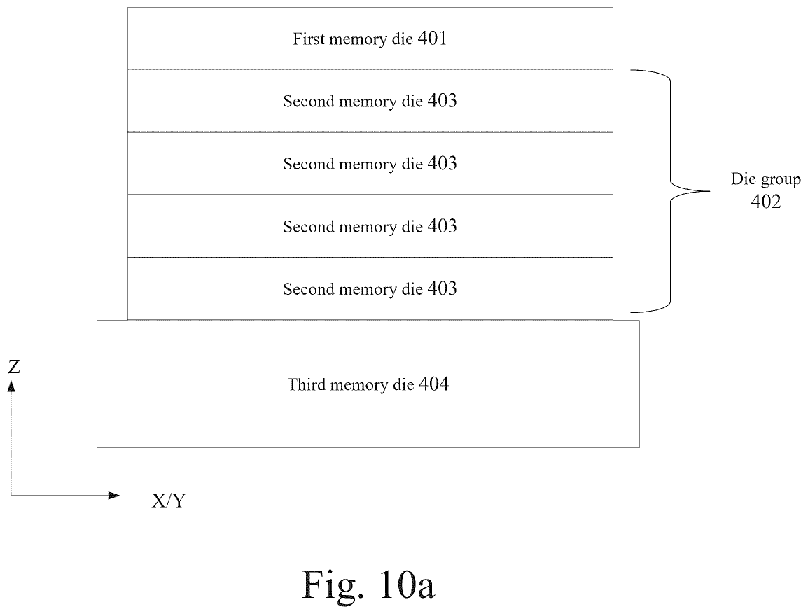

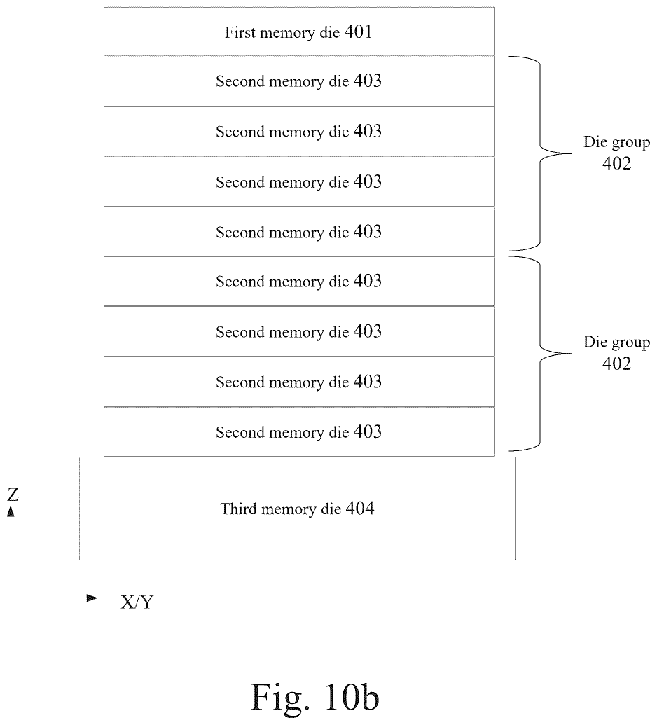

Based on a similar concept to the memory apparatus described above, a memory system is provided in an example of the present disclosure, as shown in FIGS. 10a and 5, including a memory apparatus and a third memory die 404. The third memory die 404 is stacked in the first direction (Z-axis direction) with the memory device. The memory apparatus includes a first memory die 401 and a die group 402 stacked in the first direction (Z-axis direction), where the die group 402 includes M second memory dies 403 stacked in the first direction (Z-axis direction). Each of the second memory die 403 is connected to the third memory die 404 and configured to perform data exchange at a bandwidth of (N*X) bits with the third memory die 404 through N data channels. M, N, and X are positive integers. The first memory die 401 is connected to the third memory die 404 and configured to perform data exchange at a bandwidth of (N*X) bits with the third memory die 404 through N data channels. The n data channels of the first memory die 401 and the (M*N−n) data channels of the die group 402 are configured to collectively perform data exchange with the third memory die 404 in parallel. n is an integer, 0≤n≤N.

In an example of the present disclosure, a first memory die 401 is added in the memory system. When the storage portion corresponding to the first data channel of the die group 402 fails, the first data channel corresponding to the failed storage portion is replaced with the data channel in the first memory die 401. In the first aspect, when the storage portion corresponding to the first data channel of the die group 402 fails, the die group 402 may still perform data exchange at a bandwidth of (M*N*X) bits with the third memory die 404 in parallel, so that the yield of the memory device is effectively improved. In the second aspect, the solution provided by examples of the present disclosure is a data channel level replacement, which not only solves the problem of yield loss caused by failures in the memory cell array, but also addresses the problem of yield loss caused by failures in peripheral circuitry.

In the above examples, n is an integer, 0≤n≤N. When n is equal to 0, it indicates that storage portions corresponding to the data channels of die group 402 do not fail, and there is no need to replace the data channels of die group 402. When n is greater than 0, it indicates that there is one or more data channel(s) in multiple data channels of die group 402 that corresponds to the failed storage portion. Therefore, it is beneficial to replace the data channel(s) in die group 402 that corresponds to the failed storage portion with the n data channels of die group 402.

In some examples, as shown in FIG. 10b, the die group 402 is between the first memory die 401 and the third memory die 404.

It can be understood that the die group 402 is between the first memory die 401 and the third memory die 404. That is, the first memory die is farther away from the third memory die, and the die group is closer to the third memory die, which effectively shortens the transmission path of the whole data.

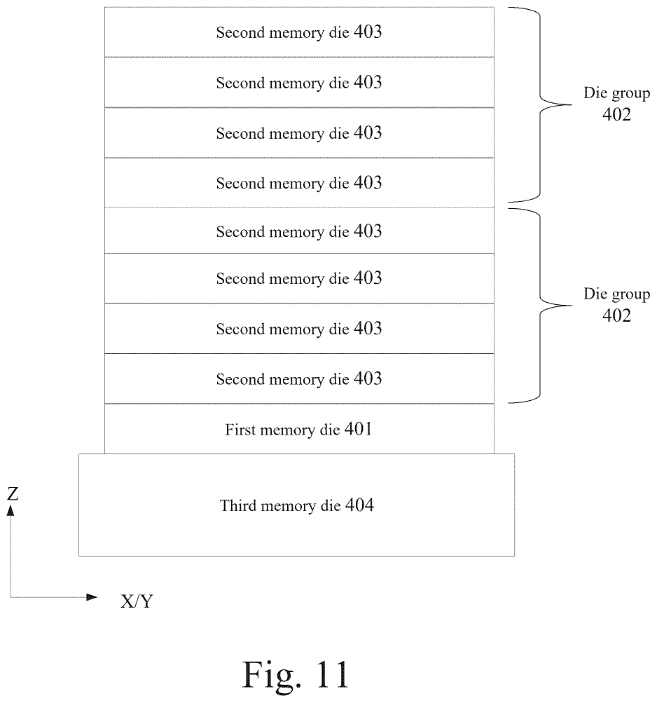

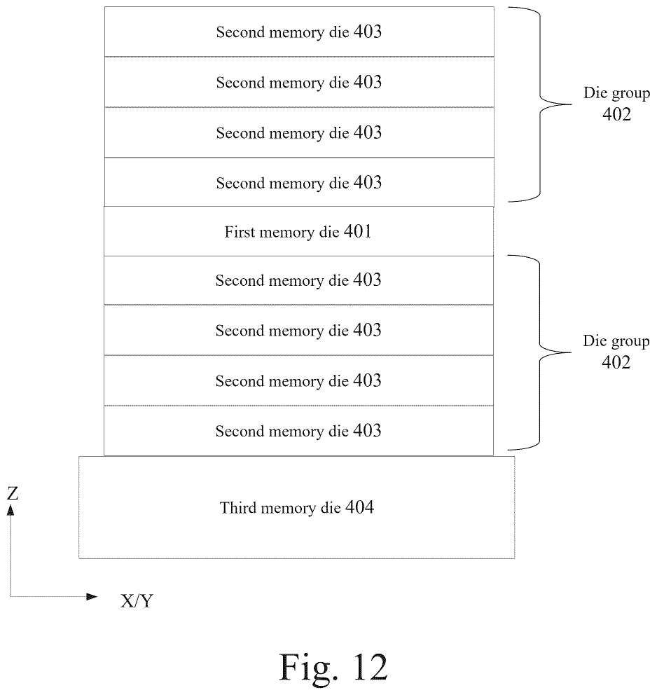

In an example of the present disclosure, as shown in FIG. 11, the first memory die 401 may also be between the die group 402 and the third memory die 404. In other examples, as shown in FIG. 12, the first memory die 401 may also be between two die groups 402 adjacent in the first direction (Z-axis direction). In yet some examples, the first memory die 401 may also be between two of the second memory dies 403 of the die group 402 adjacent in the first direction (Z-axis direction). The present disclosure is not limited thereto.

In some examples, as shown in FIGS. 10b, 11, and 12, the memory apparatus includes P die groups 402 stacked in the first direction (Z-axis direction). The first memory die 401 is configured to replace a first data channel of any one of P die groups 402 when a storage portion corresponding to the first data channel fails. P is a positive integer.

In some examples, the first memory die 401 includes a first hybrid bonding layer, and the second memory die 403 includes a second hybrid bonding layer and a third hybrid bonding layer. The first memory die 401 and the second memory die 403 are connected through the first hybrid bonding layer and the second hybrid bonding layer, and two of the second memory dies 403 adjacent in the first direction are connected to the third hybrid bonding layer through the second hybrid bonding layer.

In some examples, the first memory die 401 includes a first bump bonding layer, and the second memory die 403 includes a second bump bonding layer and a third bump bonding layer. The first memory die 401 and the second memory die 403 are connected through the first bump bonding layer and the second bump bonding layer, and two of the second memory dies 403 adjacent in the first direction are connected to the third bump bonding layer through the second bump bonding layer.

In an example of the present disclosure, the die group 402 and the first memory die 401 are stacked in the first direction, and multiple second memory dies 403 of the die group 402 are stacked in the first direction, so that the area of the memory apparatus may be saved, which facilitates miniaturization of the memory device.

In some examples, M is 4 and P is 2 or 3.

It should be noted that the values of M and P listed in the above examples are only examples and are not intended to limit the values of M and P. The values of M and P may also be set according to actual needs.

In some examples, the structure of the storage portion corresponding to the data channel of the first memory die 401 is the same as the structure of the storage portion corresponding to the data channel of the second memory die 403.

In an example of the present disclosure, the first memory die 401 and the second memory die 403 have the same structure except for the connection structure with the third memory die 404. Other structures here include the structure of the storage portion, which includes a memory cell array and peripheral circuitry.

In some examples, each of the first memory die 401 and the second memory dies 403 includes Y memory bank groups. Each of the memory bank groups includes a plurality of memory banks, and each of the memory banks includes a plurality of memory blocks. One data channel of the first memory die 401 corresponds to (Y/N) memory bank groups of the first memory die 401, and one data channel of the second memory die 403 corresponds to (Y/N) memory bank groups of the second memory die 403. Y is a positive integer and greater than N.

In some examples, each of the first memory die 401 and the second memory die 403 includes 16 memory bank groups, and has 4 data channels. One data channel of the first memory die 401 corresponds to 4 memory bank groups of the first memory die 401, and one data channel of the second memory die 403 corresponds to 4 memory bank groups of the second memory die 403. The present disclosure is not limited thereto.

In an example of the present disclosure, each of the first memory die 401 and the second memory die 403 may include a first semiconductor structure and a second semiconductor structure stacked in a first direction. The first semiconductor structure includes a memory cell array, and the second semiconductor structure includes a first portion of peripheral circuitry (e.g., sensing amplifier circuitry, word line drive circuitry, row decoders, column decoders, etc.). The third memory die includes a second portion of the peripheral circuitry, which includes the testing circuitry, a second interface, and a replacement control signal generation circuitry. The testing circuitry here may be configured to perform corresponding tests on the second memory die stacked in the first direction, the second interface may be configured to communicate with a graphics processor and central processing unit, and the replacement control signal generation circuitry may be configured to generate corresponding replacement control signals.

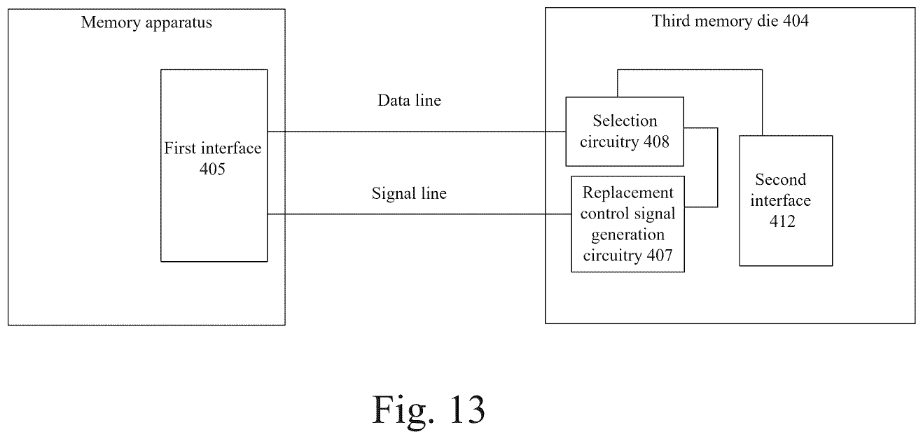

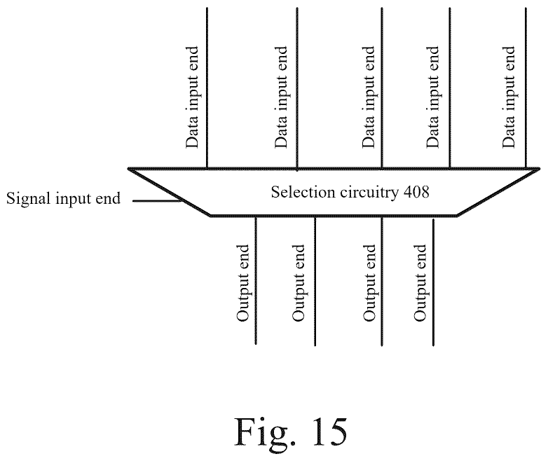

In some examples, as shown in FIGS. 13, 14, and 15, the memory apparatus includes a first interface 405 including a plurality of first data transmission interfaces 406, and each of the first data transmission interfaces corresponds to a data channel. The third memory die 404 includes a replacement control signal generation circuitry 407 and a selection circuitry 408. The selection circuitry 408 includes a signal input end and multiple data input ends. The signal input end of the selection circuitry 408 is connected to the output end of the replacement control signal generation circuitry 407. Each of the data input ends of the selection circuitry 408 is connected to a first data transmission interface 406.

Selection circuitry 408 here is connected to the first data transmission interface 406 corresponding to data channels of the first memory die 401 and the second memory die 403.

In some examples, the replacement control signal generation circuitry 407 is configured to generate a corresponding replacement control signal based on the address of the data channel corresponding to a failed storage portion in the second memory die 403, and the address of the data channel of the second memory die 403 currently requiring data exchange with the third memory die 404. The selection circuitry 408 is configured to replace the data channel corresponding to the failed storage portion in the second memory die 403 with the data channel in the first memory die 401 based on the corresponding replacement control signal.

In an example of the present disclosure, based on adding the first memory die 401, a replacement control signal generation circuitry 407 and a selection circuitry 408 are added into the third memory die 404, so as to replace a data channel corresponding to a failed storage portion in the second memory die 403 with the data channel in the first memory die 401 when the data channel in the second memory die 403 fails.

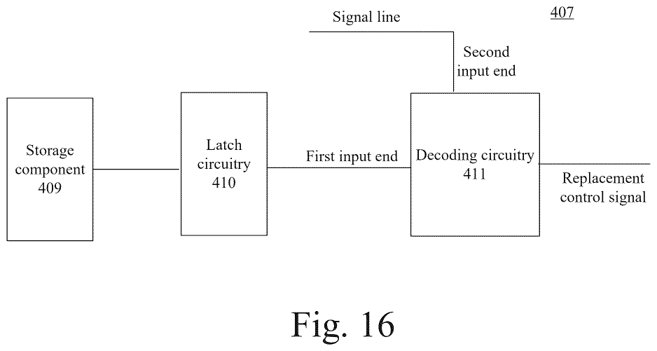

In some examples, as shown in FIG. 16, the replacement control signal generation circuitry 407 includes, e.g., storage component 409, latch circuitry 410, and decoding circuitry 411. The storage component 409 is connected to the input end of the latch circuitry 410, the output end of the latch circuitry 410 is connected to the first input end of the decoding circuitry 411, the second input end of the decoding circuitry 411 is connected to the signal line of the memory system, and the output end of the decoding circuitry 411 is connected to the signal input end of the selection circuitry 408.

In an example of the present disclosure, a failed data channel is found after testing the memory apparatus, and the address of the failed data channel is written into the storage component 409. In some examples, the storage component 409 includes electronic fuses.

In some examples, the storage component 409 is configured to store the address of the data channel corresponding to the failed storage portion in the second memory die 403. The latch circuitry 410 is configured to latch the address of the data channel corresponding to the failed storage portion in the second memory die 403 after the memory system is powered on. The decoding circuitry 411 is configured to generate a replacement control signal based on the address of the data channel corresponding to the failed storage portion in the second memory die 403 and the address of the data channel of the second memory die 403 currently requiring data exchange with the third memory die 404.

In some examples, the decoding circuitry 411 is configured to generate a replacement control signal of a first value based on the address of the data channel of the second memory die 403 currently requiring data exchange with the third memory die 404 being the same as the address of a first data channel corresponding to the failed storage portion in the second memory die 403. Different first data channels generate different first values. In some examples, the decoding circuitry 411 is configured to generate a replacement control signal of a second value based on the address of the data channel of the second memory die 403 currently requiring data exchange with the third memory die 404 being different from the address of the first data channel corresponding to a failed storage portion in the second memory die 403.

In some examples, the replacement control signal may include three bits. If the address of the data channel of the second memory die 403 currently requiring data exchange with the third memory die 404 is different from the address of the first data channel corresponding to the failed storage portion in the second memory die 403, the replacement control signal is a second value, which may be “100”, representing that there is no need to replace the data channel of the second memory die 403 currently requiring data exchange with the third memory die 404. If the address of the data channel of the second memory die 403 currently requiring data exchange with the third memory die 404 is the same as the address of the first data channel corresponding to the failed storage portion in the second memory die 403, the replacement control signal is a first value, which represents there is a need to replace the data channel of the second memory die 403 currently requiring data exchange with the third memory die 404, and different first data channels are replaced according to different first values. For example, when the first data channel is data channel 0 (CH0) of Die0, the first value is “000”; when the first data channel is data channel 4 (CH4) of Die1, the first value is “001”; when the first data channel is data channel 8 (CH8) of Die2, the first value is “010”; and when the first data channel is data channel 12 (CH12) of Die3, the first value is “011”. Of course, the number of bits for the replacement control signal provided in the above examples and the values of the first and second values are provided by way of example and not limitation. In some examples, the number of bits of the replacement control signal may be adjusted according to the number of second memory dies 403 in the die group 402 and the number of data channels in each of the second memory die 403.

In some examples, the selection circuitry 408 is configured to replace the first data channel corresponding to the first value with the data channel in the first memory die 401 based on the value of the replacement control signal being the first value.

When the replacement control signal received by the selection circuitry 408 is the first value, the selection circuitry 408 replaces the first data channel corresponding to the first value with the data channel in the first memory die 401. When the replacement control signal received by the selected circuitry is the second value, the selection circuitry 408 does not replace the data channel of the second memory die 403 in the die group 402 currently requiring data exchange with the third memory die 404.

In an example of the present disclosure, a first memory die is added, and the added first memory die utilizes a dedicated connection structure to transmit data to a third memory die. Corresponding replacement circuitry are designed in the third memory die to achieve different levels of replacement according to different degrees of failure, such as replacing a second memory die with a first memory die or a single data channel replacement at a random position.

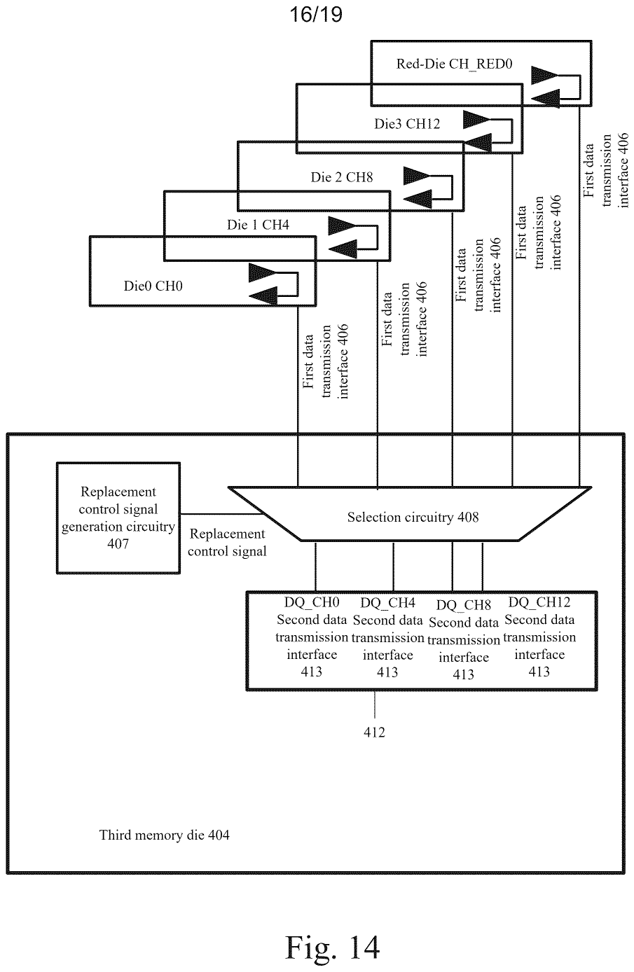

In some examples, as shown in FIG. 14, the third memory die 404 further includes a second interface 412. The second interface 412 includes multiple second data transmission interfaces 413. Each of the multiple output ends of the selection circuitry 408 is connected to a second data transmission interface 413, and the number of first data transmission interfaces 406 is greater than the number of second data transmission interfaces 413.

In an example of the present disclosure, one data channel corresponds to one of the first data transmission interfaces 406. Each data input end of the selection circuitry 408 is connected to one of the first data transmission interfaces 406, and each output end of the selection circuitry 408 is connected to one of the second data transmission interface 413. The number of data input ends of the selection circuitry 408 is greater than the number of output ends of the selection circuitry 408. Under the replacement control signal, the selection circuitry 408 will close the data input end of the selection circuitry 408 connected to the first data transmission interface 406 corresponding to the respective data channel of the failed storage portion, and open the data input end of the selection circuitry 408 connected to the first data transmission interface 406 corresponding to the respective data channel of the first memory die 401 that replaces the data channel.

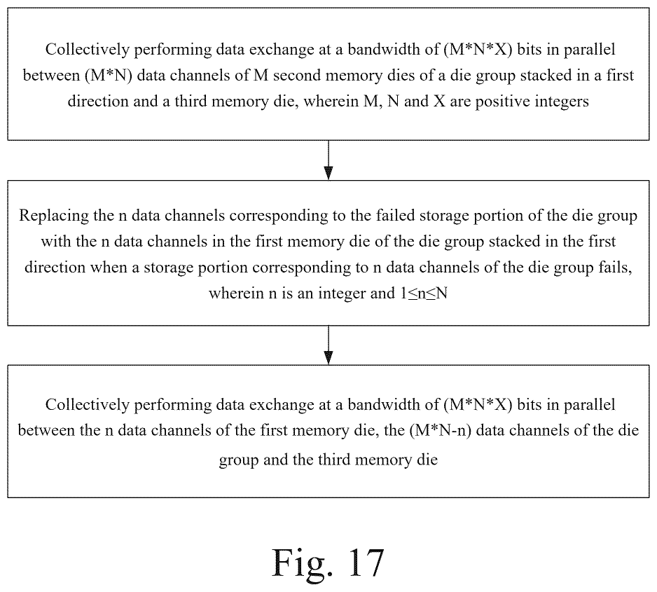

Based on the above memory system, an example of the present disclosure also provides a method of operating a memory system, as shown in FIG. 17. For example, the method may include collectively performing data exchange at a bandwidth of (M*N*X) bits between (M*N) data channels of M second memory dies of a die group stacked in a first direction and a third memory die in parallel, where M, N and X are positive integers. When a storage portion corresponding to n data channels of the die group fails, the method may include replacing the n data channels corresponding to the failed storage portion of the die group with the n data channels in the first memory die of the die group stacked in the first direction, where n is an integer and 1≤n≤N. The method may include collectively performing data exchange at a bandwidth of (M*N*X) bits between the n data channels of the first memory die, the (M*N−n) data channels of the die group and the third memory die in parallel.

It should be understood that the steps shown in FIG. 17 are not exclusive and other steps may be performed before, after, or between any one of the steps in the operation shown. The order of the steps shown in FIG. 17 may be adjusted according to actual needs.

In some examples, when the storage portion corresponding to the n data channels of the die group fails, replacing the n data channels corresponding to the failed storage portion of the die group with the n data channels in the first memory die of the die group stacked in the first direction may include, when the storage portion corresponding to the n data channels of any one of the P die groups of the memory system stacked in the first direction fails, the n data channels in the first memory die are utilized to replace the n data channels of the die group where the storage portion fails; P is a positive integer.

In some examples, the die group is between the first memory die and the third memory die.

In some examples, when the storage portion corresponding to the n data channels of the die group fails, replacing the n data channels corresponding to the failed storage portion of the die group with the n data channels in the first memory die of the die group stacked in the first direction may include generating, by a replacement control signal generation circuitry, a corresponding replacement control signal based on the address of the data channel corresponding to the failed storage portion in the second memory die and the address of the data channel of the second memory die currently requiring data exchange with the third memory die. In some examples, when the storage portion corresponding to the n data channels of the die group fails, replacing the n data channels corresponding to the failed storage portion of the die group with the n data channels in the first memory die of the die group stacked in the first direction may include replacing, by a selection circuitry, the data channel corresponding to the failed storage portion in the second memory die with the data channel in the first memory die based on the corresponding replacement control signal.

In some examples, generating, by the replacement control signal generation circuitry, a corresponding replacement control signal based on the address of the data channel corresponding to the failed storage portion in the second memory die and the address of the data channel of the second memory die currently requiring data exchange with the third memory die may include storing, by a storage component, the address of the data channel corresponding to the failed storage portion in the second memory die. In some examples, generating, by the replacement control signal generation circuitry, a corresponding replacement control signal based on the address of the data channel corresponding to the failed storage portion in the second memory die and the address of the data channel of the second memory die currently requiring data exchange with the third memory die may include latching, by a latch circuitry, the address of the data channel corresponding to the failed storage portion in the second memory die, after the memory system is powered on. In some examples, generating, by the replacement control signal generation circuitry, a corresponding replacement control signal based on the address of the data channel corresponding to the failed storage portion in the second memory die and the address of the data channel of the second memory die currently requiring data exchange with the third memory die may include generating, by a decoding circuitry, a corresponding replacement control signal based on the address of the data channel corresponding to the failed storage portion in the second memory die and the address of the data channel of the second memory die currently requiring data exchange with the third memory die.

In some examples, the method further includes generating, by the decoding circuitry, a replacement control signal of a first value based on the address of the data channel of the second memory die currently requiring data exchange with the third memory die being the same as the address of the first data channel corresponding to the failed storage portion in the second memory die, where different first data channels generate different first values. In some examples, the method further includes generating, by the decoding circuitry, a replacement control signal of a second value based on the address of the data channel of the second memory die currently requiring data exchange with the third memory die is different from the address of the first data channel corresponding to the failed storage portion in the second memory die.

In some examples, the method further includes replacing, by the selection circuitry, the first data channel corresponding to the first value with the data channel in the first memory die based on the value of the replacement control signal being the first value.

The details related to the method of operating the memory system described above have been introduced in detail in the previous examples regarding the memory apparatus and memory system, and will not be described any more for the purpose of simplicity.

The features disclosed in several apparatus examples provided by the present disclosure may be combined arbitrarily without conflict to obtain new apparatus examples.

The methods disclosed in several method examples provided by the present disclosure may be combined arbitrarily without conflict to obtain new method examples.

The above is only detailed implementations of the present disclosure, and the scope of the present disclosure is not limited thereto. A person having ordinary skill in the art will readily recognize that variations or replacements within the technical scope disclosed in the present disclosure should be included in the scope of the present disclosure.

What is claimed is:

1. A memory apparatus, comprising:
a first memory die and a die group stacked in a first direction,
wherein the die group comprises M second memory dies stacked in the first direction, and each of the second memory dies is connected to a third memory die and configured to perform data exchange at a bandwidth of (N*X) bits with the third memory die through N data channels, wherein M, N and X are positive integers, and
wherein the first memory die is connected to the third memory die, and configured to perform data exchange at a bandwidth of (N*X) bits with the third memory die through N data channels, and to replace a first data channel of the die group when a storage portion corresponding to the first data channel fails.

2. The memory apparatus of claim 1, further comprising:
P die groups stacked in the first direction,
wherein the first memory die is configured to replace a first data channel of any one of the P die groups when a storage portion corresponding to the first data channel fails, and P is a positive integer.

3. The memory apparatus of claim 1, wherein:
the first memory die comprises a first hybrid bonding layer,
each second memory die of the M second memory dies comprises a second hybrid bonding layer and a third hybrid bonding layer,
the first memory die and the second memory die are connected through the first hybrid bonding layer and the second hybrid bonding layer, and
two of the second memory dies adjacent in the first direction are connected to the third hybrid bonding layer through the second hybrid bonding layer.

4. The memory apparatus of claim 1, wherein:
the first memory die comprises a first bump bonding layer,
each second memory die of the M second memory dies comprises a second bump bonding layer and a third bump bonding layer,
the first memory die and the second memory die are connected through the first bump bonding layer and the second bump bonding layer, and
two of the second memory dies adjacent in the first direction are connected to the third bump bonding layer through the second bump bonding layer.

5. The memory apparatus of claim 2, wherein the first memory die is on one of two opposite sides of the P die groups in the first direction.

6. The memory apparatus of claim 2, wherein M is 4 and P is 2 or 3.

7. The memory apparatus of claim 1, wherein a structure of the storage portion corresponding to the data channel of the first memory die is the same as a structure of the storage portion corresponding to the data channel of a second memory die of the M second memory dies.

8. The memory apparatus of claim 1, wherein:
each of the first memory die and the second memory dies comprises Y memory bank groups, each of the memory bank groups comprises a plurality of memory banks, and each of the memory banks comprises a plurality of memory blocks, and
one data channel of the first memory die corresponds to (Y/N) memory bank groups of the first memory die, and one data channel of a second memory die of the M second memory dies corresponds to (Y/N) memory bank groups of the second memory die, wherein Y is a positive integer and greater than N.

9. A memory system, comprising:
a memory apparatus and a third memory die,
wherein the third memory die and the memory apparatus are stacked in a first direction, the memory apparatus comprises a first memory die and a die group stacked in the first direction, the die group comprises M second memory dies stacked in the first direction,
wherein each of the second memory dies is connected to the third memory die and configured to perform data exchange at a bandwidth of (N*X) bits with the third memory die through N data channels, wherein M, N and X are positive integers, and
wherein the first memory die is connected with the third memory die and configured to perform data exchange at a bandwidth of (N*X) bits with the third memory die through N data channels, and n data channels of the first memory die and (M*N−n) data channels of the die group are configured to collectively perform data exchange with the third memory die in parallel, wherein n is an integer, and 0≤n≤N.

10. The memory system of claim 9, wherein the die group is between the first memory die and the third memory die.

11. The memory system of claim 9, wherein:
the memory apparatus comprises P die groups stacked in the first direction,
the first memory die is configured to replace a first data channel of any one of the P die groups when a storage portion corresponding to the first data channel fails, and
P is a positive integer.

12. The memory system of claim 9, wherein:
the first memory die comprises a first hybrid bonding layer,
each second memory die of the M second memory dies comprises a second hybrid bonding layer and a third hybrid bonding layer,
the first memory die and the second memory die are connected through the first hybrid bonding layer and the second hybrid bonding layer, and
two of the second memory dies adjacent in the first direction are connected to the third hybrid bonding layer through the second hybrid bonding layer.

13. The memory system of claim 9, wherein:
the first memory die comprises a first bump bonding layer,
each second memory die of the M second memory dies comprises a second bump bonding layer and a third bump bonding layer,
the first memory die and the second memory die are connected through the first bump bonding layer and the second bump bonding layer, and
two of the second memory dies adjacent in the first direction are connected to the third bump bonding layer through the second bump bonding layer.

14. The memory system of claim 11, wherein M is 4 and P is 2 or 3.

15. The memory system of claim 9, wherein a structure of a storage portion corresponding to the data channel of the first memory die is the same as a structure of a storage portion corresponding to the data channel of a second memory die of the M second memory dies.

16. The memory system of claim 9, wherein:
each of the first memory die and the second memory dies comprises Y memory bank groups, each of the memory bank groups comprises a plurality of memory banks, and each of the memory banks comprises a plurality of memory blocks, and
one data channel of the first memory die corresponds to (Y/N) memory bank groups of the first memory die, and one data channel of a second memory die of the M second memory dies corresponds to (Y/N) memory bank groups of the second memory die, wherein Y is a positive integer and greater than N.

17. The memory system of claim 9, wherein:
the memory apparatus comprises a first interface comprising a plurality of first data transmission interfaces, and each of the first data transmission interfaces corresponds to one data channel; and
the third memory die comprises:
a replacement control signal generation circuitry; and
a selection circuitry comprising a signal input end and a plurality of data input ends,
wherein the signal input end of the selection circuitry is connected to an output end of the replacement control signal generation circuitry, and each of the data input ends of the selection circuitry is connected to one of the first data transmission interfaces.

18. The memory system of claim 17, wherein:
the replacement control signal generation circuitry is configured to generate a corresponding replacement control signal based on an address of the data channel corresponding to a failed storage portion in a second memory die of the M second memory dies and an address of the data channel of the second memory die currently requiring data exchange with the third memory die, and
the selection circuitry is configured to replace the data channel corresponding to the failed storage portion in the second memory die with the data channel in the first memory die based on the corresponding replacement control signal.

19. The memory system of claim 18, wherein the replacement control signal generation circuitry comprises:
a storage component, a latch circuitry, and a decoding circuitry,
wherein the storage component is connected to an input end of the latch circuitry, an output end of the latch circuitry is connected to a first input end of the decoding circuitry, a second input end of the decoding circuitry is connected to a signal line of the memory system, and an output end of the decoding circuitry is connected to the signal input end of the selection circuitry.

20. A method of operating a memory system, comprising:
collectively performing data exchange at a bandwidth of (M*N*X) bits in parallel between (M*N) data channels of M second memory dies of a die group stacked in a first direction and a third memory die, wherein M, N and X are positive integers;
when a storage portion corresponding to the n data channels of the die group fails, replacing n data channels corresponding to a failed storage portion of the die group with n data channels in a first memory die of the die group stacked in the first direction, wherein n is an integer and 1≤n≤N; and
collectively performing data exchange at a bandwidth of (M*N*X) bits in parallel between the n data channels of the first memory die, the (M*N-n) data channels of the die group and the third memory die.
